(19) United States
(12) Patent Application Publication
(10) Pub. No.: US 2006/0261358 A1
(43) Pub. Date: Nov. 23, 2006

(54) Flip chip light emitting diode and method of manufacturing the same

(75) Inventors: Seok Min Hwang, Suwon (KR); Je Won Kim, Suwon (KR); Young Ho Park, Suwon (KR); Min Ju Kim, Gimhae (KR); Hyo-Kyoung Cho, Suwon (KR); Kun Yoo Ko, Hwaseong (KR); Bok Ki Min, Cheongju (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/414,362

(22) Filed: May 1, 2006

(30) Foreign Application Priority Data
May 3, 2005 (KR) 10-2005-0037220

(51) Int. Cl. H01L 33/00

(52) U.S. Cl. 257/91

(57) ABSTRACT

The present invention relates to a flip chip light emitting diode in which an n-type electrode is formed on an insulating layer so that a large light emitting area can be secured to thereby enhance a current-spreading effect and in which the n-type electrode serves as a light reflecting layer so that light is prevented from being transmitted into the rear surface to thereby enhance light emission efficiency. The flip chip light emitting diode includes an optically-transparent substrate; a light emitting substrate that is formed by sequentially laminating an n-type nitride semiconductor layer, an active layer, a p-type nitride semiconductor layer on the substrate and that includes mesas which are formed by etching the active layer and the p-type nitride semiconductor layer into a predetermined width so that a plurality of regions of the n-type nitride semiconductor layer are exposed; a plurality of p-type electrodes that are formed on the p-type nitride semiconductor layer of the light emitting structure; an insulating layer that is formed on the surface of the light emitting structure from a portion of the plurality of p-type electrodes to a portion of the n-type nitride semiconductor layer of the mesa; and an n-type electrode that is formed across the insulating layer and the mesa and comes in contact with the exposed n-type nitride semiconductor layer of the mesa.

### CROSS-REFERENCE TO RELATED APPLICATIONS

The application claims the benefit of Korea Patent Application No. 2005-0037220 filed with the Korea Industrial Property Office on May 3, 2005, the disclosure of which is incorporated herein by reference.

### BACKGROUND OF THE INVENTION

1. Field of the Invention

The present invention relates to a flip chip light emitting diode and a method of manufacturing the same, and more specifically, to a flip chip light emitting diode in which a current-spreading effect can be enhanced even though the width of a mesa is minimized in comparison with that of an existing chip and the light transmitted into the rear surface is reflected to thereby enhance light emission efficiency, and a method of manufacturing the same.

2. Description of the Related Art

In general, a light emitting diode (LED) is such an element that converts an electrical signal into the form of infrared rays, ultraviolet rays or light so as to send and receive signals by using the characteristics of a compound semiconductor such as the recombining of electrons and holes.

A light emitting diode is generally used in a home appliance, a remote control, an electronic display board, a marker, an automation equipment, an optical communication, or the like. The light emitting diode is roughly divided into an IRED (infrared emitting diode) and VLED (visible light emitting diode).

In a light emitting diode, the frequency (or wavelength) of emitted light is utilized as a band-gap function of a material used in the semiconductor device. When a semiconductor material having a small band gap is used, a photon having low energy and a long wavelength is generated. When a semiconductor material having a large band gap is used, a photon having a short wavelength is generated. Accordingly, a semiconductor material is selected according to the type of light which is desired to be emitted.

In the case of a red light emitting diode, a material such as AlGaInP is used. In the case of a blue light emitting diode, silicon carbide (SiC) and gallium nitride (GaN) as a nitride semiconductor of the group III are used. Recently, as a nitride semiconductor used in a blue light emitting diode, (AlₓIn₁₋ₓ)_{y}Ga_{1-y}N (0≦x≦1 and 0≦y≦1) is widely used.

Among them, since bulk single-crystal GaN cannot be formed in a gallium-base light emitting diode, a substrate suitable for the growth of GaN crystal should be used. Sapphire is representatively used.

FIG. 1 is a cross-sectional view illustrating a GaN light emitting diode according to the related art. The GaN light emitting diode 7 includes a sapphire growth substrate 1, a GaN light emitting structure 2 which is formed by sequentially laminating an n-type nitride semiconductor layer, an active layer, and a p-type nitride semiconductor layer on the sapphire substrate 1, a p-type electrode 3 which is formed on the GaN light emitting structure 2, and an n-type electrode 4.

In the GaN light emitting structure 2, the p-type nitride semiconductor layer and the active layer are mesa-etched to expose a portion of the upper surface of the n-type nitride semiconductor layer. On the exposed upper surface of the n-type nitride semiconductor layer and the unetched upper surface of the p-type nitride semiconductor layer, an n-type electrode 4 and a p-type electrode 3 are respectively formed so as to apply a predetermined voltage. In general, in order not to have a bad influence on the brightness of light generated while increasing a current injection area, a transparent electrode can be formed on the upper surface of the p-type nitride semiconductor layer before the p-type electrode 3 is formed.

The p-type electrode is formed by sequentially laminating p-type ohmic metal 3a, barrier metal 3b, and bonding metal 3c. After the p-type and n-type electrodes 3 and 4 are formed, an insulating body formed of a transparent nonconductor film is laminated on the electrodes, and a portion of the insulating body is etched so that the formed electrodes 3 and 4 are exposed, thereby forming an insulating layer 6 for protecting the light emitting structure.

The GaN-based light emitting diode having such a construction can be manufactured as a light emitting diode package through a die bonding process by a chip-side-up method. In this case, light emits in the direction where the p-type and n-type electrodes 3 and 4 are formed. In the portion where the electrodes 3 and 4 are formed, light cannot be emitted. Further, the radiation of heat generated in a chip when light is emitted is reduced due to low heat conductivity of sapphire, thereby reducing the lifetime of the light emitting diode.

In order to solve the problems, the GaN-based light emitting diode can be constructed in the form of a flip chip in which the light emitting diode 7 of FIG. 1 is turned upside down and the p-type and n-type electrodes 3 and 4 are directly mounted on a printed circuit board or lead frame through a die bonding process so that the direction of light emission is set to the direction where the sapphire substrate 1 is formed.

In such a flip chip light emitting diode, predetermined regions of the active layer and p-type nitride semiconductor layer are etched to expose a plurality of regions of the n-type nitride semiconductor layer, in order to form more than one n-type electrode. In this case, the exposed portion is referred to as a mesa 5. On the mesa, the n-type electrode and insulating body are formed, thereby manufacturing a light emitting diode chip.

FIG. 2 is a diagram showing a state where a light emitting diode according to the related art is flip-chip bonded.

As shown in FIG. 2, the light emitting diode includes a sapphire substrate 1, a light emitting structure 2 which is formed by sequentially laminating an n-type nitride semiconductor layer, an active layer, and a p-type nitride semiconductor layer on the sapphire substrate 1, a p-type electrode 3 which is formed by sequentially laminating p-type ohmic metal 3a, barrier metal 3b, and bonding metal 3c on a predetermined position of the light emitting structure 2, and an n-type electrode 4 which is formed on a predetermined region of the n-type nitride semiconductor layer so as to be used for bonding or applying a voltage. Such a light emitting diode is directly joined to a silicon submount 10 with a solder bump 11 interposed therebetween, the solder bump 10 being formed on the p-type and n-type electrodes 3 and 4. At this time, the p-type and n-type electrodes 3 and 4 are respectively connected to the anode 12 and cathode 13, which are formed on the silicon submount 10, through the solder bump 11.

FIG. 3 is a plan view illustrating the light emitting diode including the n-type electrode according to the related art. The n-type electrode 4 typically has a width of 15 to 30 μm, and the insulating body typically has a width of 10 to 20 μm. Therefore, the mesa needs to have a width of at least 25 to 50 μm so that the n-type electrode 4 and the insulating body are formed in the mesa. In the light emitting diode, however, it is preferable that more than one n-type electrode be arranged to have a minimum gap, in order to enhance a current-spreading effect. In the related art as shown in FIG. 3, when more than one n-type electrode 4 is arranged, a ratio of the entire area of a chip to the area of the mesa 5 for forming the n-type electrode 4 increases. Then, the area of a portion contributing to the light emission is reduced.

FIG. 4 is a cross-sectional view showing a state where the light emitting diode according to the related art is mounted in the form of a flip chip. When the n-type electrode 4 and the insulating body are formed in the mesa, a gap d as much as a space where the insulating layer is formed is generated.

The n-type ohmic metal composing the n-type electrode 4 typically includes Ag, Al, Pd, and the like, which have a characteristic of reflecting light. On the other hand, since the insulating body composing the insulating body is typically formed of a SiO₂ nonconductor film, the insulating body does not have a characteristic of reflecting light. Therefore, although the insulating layer is formed in the gap d, the light generated in the active layer is not reflected into the light emitting structure 2 but is transmitted into the rear surface through the distance d, as shown in FIG. 4. As a result, the light emission efficiency is reduced.

### SUMMARY OF THE INVENTION

An advantage of the present invention is that it provides a flip chip light emitting diode in which an n-type electrode is formed on an insulating layer so that the overall area of the n-type electrode can be set to be the same as an existing chip even though the width of a mesa is minimized in comparison with the existing chip to thereby enhance a current-spreading effect, and a method of manufacturing the same.

Another advantage of the invention is that it provides a flip chip light emitting diode in which an n-type electrode is formed on an insulating layer so that the light, which has been transmitted into the rear surface of a light emitting structure in the related art, is reflected to thereby enhance light emission efficiency, and a method of manufacturing the same.

Additional aspects and advantages of the present general inventive concept will be set forth in part in the description which follows and, in part, will be obvious from the description, or may be learned by practice of the general inventive concept.

According to an aspect of the invention, a flip chip light emitting diode includes an optically-transparent substrate; a light emitting substrate that is formed by sequentially laminating an n-type nitride semiconductor layer, an active layer, a p-type nitride semiconductor layer on the substrate and that includes mesas which are formed by etching the active layer and the p-type nitride semiconductor layer into a predetermined width so that a plurality of regions of the n-type nitride semiconductor layer are exposed; a plurality of p-type electrodes that are formed on the p-type nitride semiconductor layer of the light emitting structure; an insulating layer that is formed on the surface of the light emitting structure from a portion of the plurality of p-type electrodes to a portion of the n-type nitride semiconductor layer of the mesa; and an n-type electrode that is formed across the insulating layer and the mesa and comes in contact with the exposed n-type nitride semiconductor layer of the mesa.

The width of the mesa of the light emitting structure is in the range of 5 to 25 μm.

The plurality of p-type electrodes are formed by sequentially laminating p-type ohmic metal, barrier metal, and bonding metal.

The insulating layer is formed across the surface of the light emitting structure from a portion of the barrier metal or bonding metal to a portion of the n-type nitride semiconductor layer of the mesa.

A method of manufacturing a flip chip light emitting diode includes sequentially forming an n-type nitride semiconductor layer, an active layer, a p-type nitride semiconductor layer on an optically-transparent substrate; etching predetermined regions of the active layer and p-type nitride semiconductor layer and exposing a plurality of regions of the n-type nitride semiconductor layer so as to form a plurality of mesas; forming a plurality of p-type electrodes on the p-type nitride semiconductor layer; forming an insulating body on a light emitting structure including the mesas and the plurality of p-type electrodes and then etching the insulating body so that portions of the plurality of p-type electrodes and the n-type nitride semiconductor layer of the mesa are exposed; and forming an n-type electrode across the insulating layer and the mesa so that the n-type electrode comes in contact with the exposed n-type nitride semiconductor layer of the mesa.

In forming the mesa, etching is performed so that the width of the mesa corresponds to the range of 5 to 25 μm.

In forming the p-type electrode, p-type ohmic metal, barrier metal, and bonding metal are sequentially laminated.

In forming the insulating layer, the insulating body is etched so that a portion of the barrier metal, the overall portion of the bonding metal, and a portion of the bonding metal are exposed.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view illustrating a light emitting diode according to the related art;

FIG. 2 is a cross-sectional view showing a state where the light emitting diode according to the related art is flip-chip bonded;

FIG. 3 is a plan view illustrating a light emitting diode including an n-type electrode according to the related art;

FIG. 4 is a cross-sectional view showing a state where the light emitting diode according to the related art is mounted in the form of a flip chip;

FIG. 5 is a cross-sectional view illustrating a light emitting diode according to the present invention;

FIG. 6 is a diagram comparatively showing the cross-sections of the light emitting diodes according to the related art and according to the present invention;

FIG. 7 is a cross-sectional view showing a state where the light emitting diode according to the invention is mounted in the form of a flip chip;

FIG. 8 is a flow chart showing a method of manufacturing the light emitting diode according to the invention; and

FIGS. 9A to 9E are cross-sectional views showing a process of manufacturing the light emitting diode according to the invention.

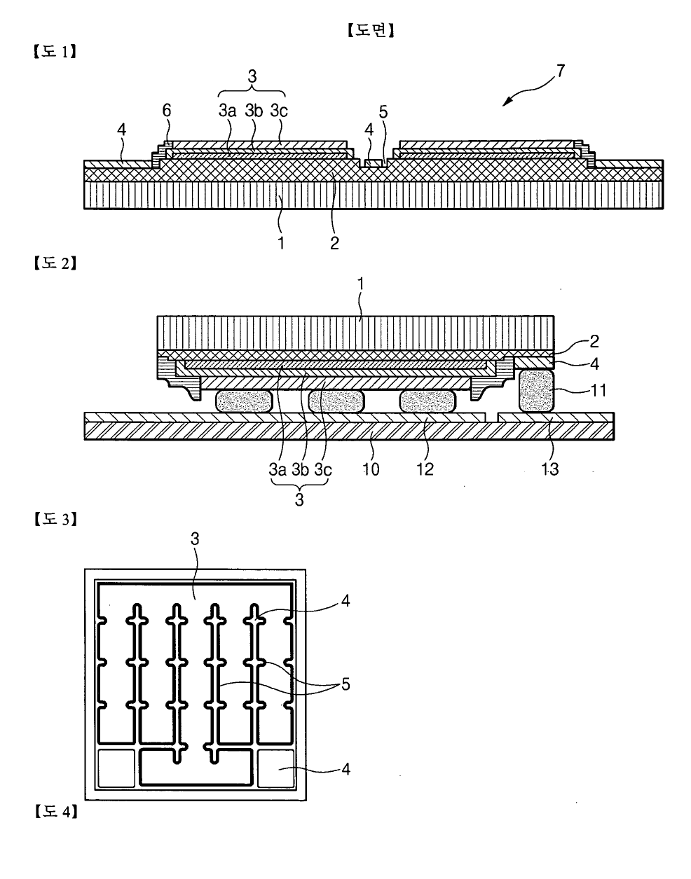

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

Hereinafter, a preferred embodiment of the present invention will be described in detail with reference to the accompanying drawings.

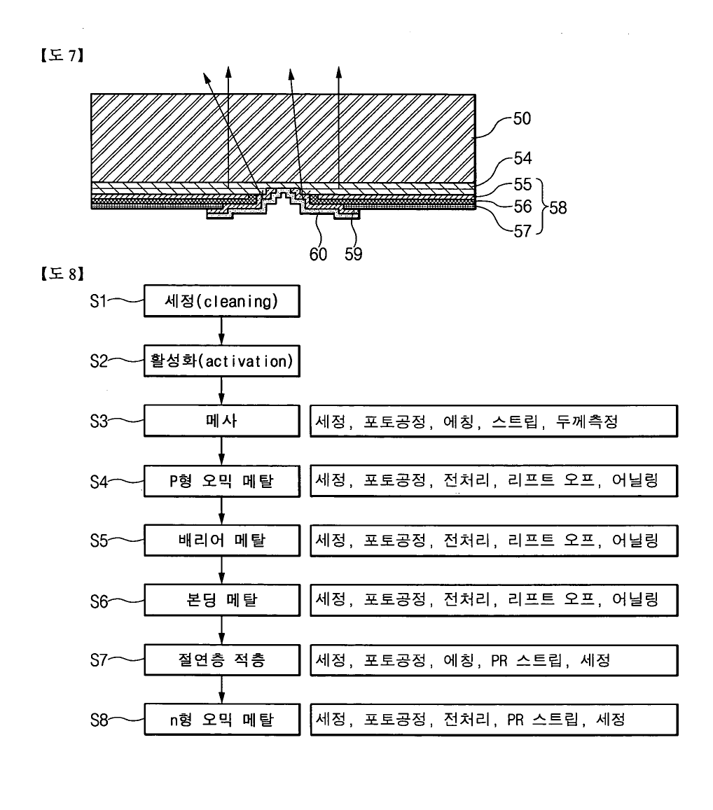

FIG. 5 is a cross-sectional view illustrating a light emitting diode according to the present invention. As shown in FIG. 5, the light emitting diode according to the invention includes an optically-transparent sapphire substrate 50 and a light emitting structure 54 in which an n-type nitride semiconductor layer 51, an active layer 52 having a multi-quantum well structure, and a p-type nitride semiconductor layer 53 are sequentially laminated on the sapphire substrate 50. The light emitting structure 54 is composed of a plurality of mesas (not shown), which are formed by etching the p-type nitride semiconductor layer 53 and active layer 52 and exposing a portion of the upper surface of the n-type nitride semiconductor layer 51, and a p-type electrode 58 in which p-type ohmic metal 55, barrier metal 56, and bonding metal 57 are sequentially laminated on the p-type nitride semiconductor layer 53.

The light emitting structure 54, in which the n-type nitride semiconductor layer 51, the active layer 52, and the p-type nitride semiconductor layer 53 are sequentially laminated on the optically-transparent sapphire substrate 50, can be manufactured by using a MOCVD (metal organic chemical vapor deposition) method or the like. In the MOCVD method, a material composed of a volatile alkyl compound which is an organic metal compound of the group III and a hydrogen compound of the group V is vapor-thermally decomposed into a III-V group compound. Such a method is preferably used in manufacturing a high-brightness light emitting diode, because a very thin growth layer corresponding to the MBE level can be grown and a thin film with good quality can be reproduced and mass-produced, even though the used material is poisonous and explosive. At this time, before the n-type nitride semiconductor layer 51 is grown, a buffer layer (not shown) composed of AIN/GaN can be formed, in order to improve the lattice matching with the sapphire substrate 50.

In general, the active layer 52 has such structures as a double hetero structure and a single or multi quantum well structure. In the double hetero structure, the active layers 52 of a light emitting region are grown to have a thickness of 10 to 100 nm, and a donor and acceptor are co-doped so that the active layers are radiatively recombined from the donor-acceptor pair (DAP). In the single or multi quantum well structure, light emitting layers are manufactured with a thickness of 1 to 10 nm so as to form a quantum well structure and thus are radiatively recombined through the band-to-band transition. It is preferable to manufacture a thin light emitting diode having a quantum structure in which the thickness of the active layer 52 does not exceed a pseudomorphic critical layer thickness where an electric potential is not generated due to dislocation caused by the lattice mismatch between respective semiconductor thin layers.

The mesa formed in the light emitting structure 54 is formed as follows: the active layer 52 and the p-type nitride semiconductor layer 53 are grown across the overall portion of the n-type nitride semiconductor layer 51, and predetermined regions of the grown active layer 52 and p-type nitride semiconductor layer 53 are etched. As an etching method when the mesa is formed, an RIE method is preferably used. In the RIE method, the mesa can be accurately etched to have a desired shape, compared with a wet etching method. Further, an angle with respect to the cross-section of the mesa can be easily adjusted to thereby improve light emission efficiency.

The p-type electrode 58 includes the p-type ohmic metal 55, the barrier metal 56, and the bonding metal 57 which are sequentially laminated on the p-type nitride semiconductor layer 53.

The p-type ohmic metal 55 is formed of a material selected from a group composed of Pt, Rh, Pd/Ni/Al/Au, Ni—La solid solution/Au, Pd/Au, Ti/Pt/Au, Pd/Ni, Zn—Ni solid solution/Au, InGaN, Ni/Pd/Au, Ni—La solid solution/Au, Pd/Au, Ti/Pt/Au, Pd/Ni, Pt/Ni/Au, Ta/Ti, Ru/Ni, and Au/Ni/Au.

The barrier metal 56 is laminated, in order to prevent metal for ohmic contact and the uppermost metal layer for wiring from being alloyed. The barrier metal 56 can be typically formed of an alloy of Cr/Ni or Ti and W.

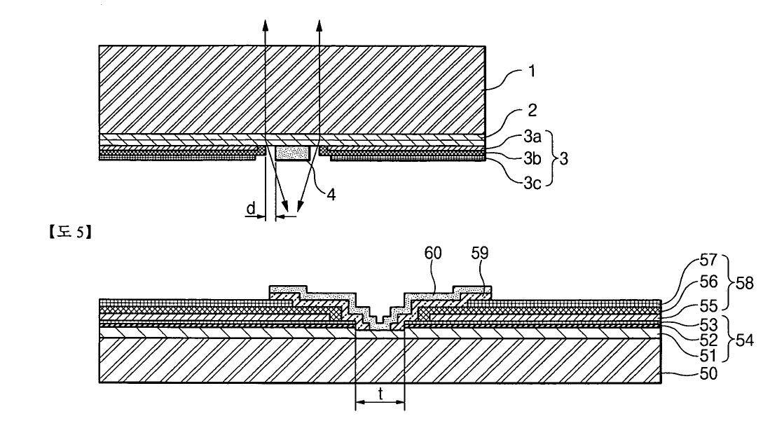

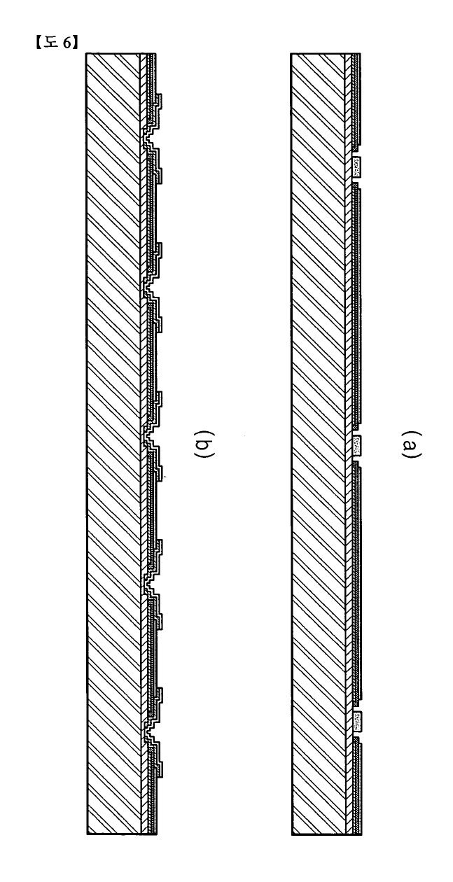

The bonding metal 57 is bonded to an electrode formed on a silicon submount (refer to FIG. 2A) of which the thermal expansion coefficient is similar to that of the sapphire substrate 50. The bonding metal 57 is typically formed of Cr/Au.

The insulating layer 59 is formed across the surface of the light emitting structure 54 from the upper portion of the barrier metal 56 of the p-type electrode 58 to the exposed n-type nitride semiconductor layer of the mesa in such a shape that the insulating layer 59 comes in contact with the exposed n-type nitride semiconductor layer of the mesa. The insulating layer 59 is preferably formed of SiO₂. In addition to that, an insulating material such as Si₃N₄, Al₂O₃, or the like can be used.

Across the insulating layer 59 and the mesas, an n-type electrode 60 is formed to come in contact with the exposed n-type nitride semiconductor layer of the mesa. In such a structure, n-type ohmic metal is laminated. The n-type ohmic metal is formed of a material selected from a group composed of Ti/Ag, Ti/Al, Pd/Al, Ni/Au, Si/Ti, ITO, Ti/Al/Pt/Au, ITO/ZnO, Ti/Al/Ni/Au, and Al.

Therefore, an area where the n-type nitride semiconductor layer 51 and the n-type electrode 60 come in contact with each other on the mesa is reduced, compared with the case in the related art. However, since the n-type electrode 60 is formed across the surface of the insulating layer 59, the overall area of the n-type electrode 60 can be set to be substantially the same as that of an existing chip.

The mesa according to the related art needs to have a width of at least 25 to 50 μm. In the present invention, however, the width t of the mesa can be reduced to less than 25 μm. Accordingly, although the mesa is designed to have a width t of less than 25 μm, the n-type electrode 60 is formed on the insulating layer 59 so that the overall area of the n-type electrode 60 can be substantially the same as that of an existing chip. As a result, a light emitting area is expanded, thereby enhancing a current-spreading effect.

In FIGS. 6A and 6B, the cross-sectional construction of the light emitting diode according to the related art is compared with that of the light emitting diode according to the invention. It can be found that more n-type electrodes 60 can be arranged in the light emitting structure (refer to FIG. 6B) according to the invention than in the light emitting structure (refer to FIG. 6A) according to the related art, even though they have the same area.

In the case of 1000 μm×1000 μm large-output light emitting diode chip, the width t of the mesa is reduced, because about ten of the n-type electrodes 60 can be formed in accordance with the present invention. Furthermore, a light emitting area is expanded more than that of an existing chip in which three n-type electrodes are arranged at the minimum gap, thereby enhancing light emission efficiency and a current-spreading effect.

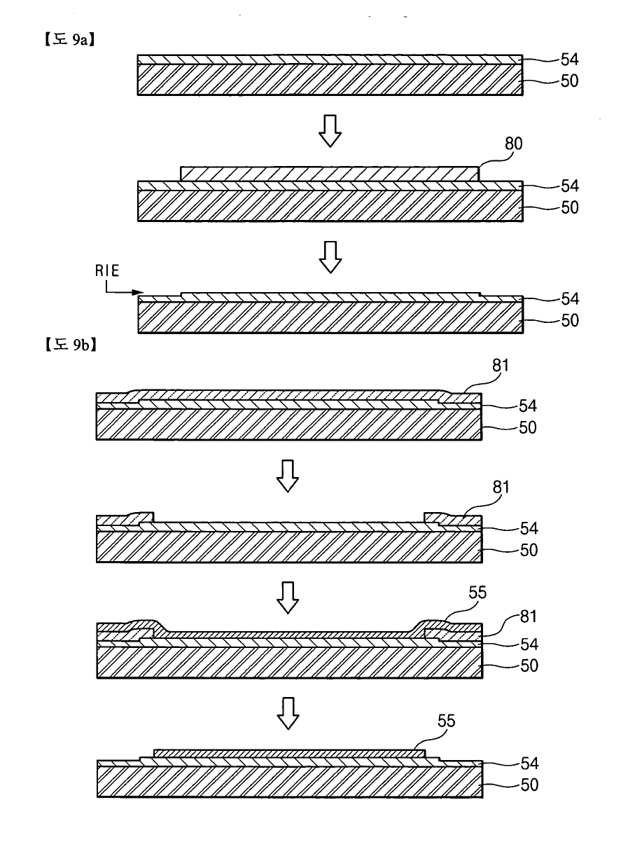

FIG. 7 is a cross-sectional view showing a state where the light emitting diode according to the present invention is mounted in the form of a flip chip. In the related art, if the n-type electrode and insulating layer are formed on the mesa, a gap as much as a space where the insulating layer is formed is generated. Although the insulating layer is formed in the gap, the light generated in the active layer is not reflected into the light emitting structure but is transmitted into the rear surface through such a gap, thereby reducing light emission efficiency. In the present invention, however, the n-type electrode 60 is formed on the insulating layer 59, as shown in FIG. 7. Accordingly, a gap as much as a space where the insulating layer 59 is formed is not generated, so that the light is not transmitted into the rear surface.

Since the n-type electrode 60 formed across the surface of the insulating layer typically includes a reflecting material such as Ag, Al, Pd, or the like, the light generated in the active layer is reflected into the light emitting diode, thereby enhancing the light emission efficiency of the light emitting diode.

FIG. 8 is a flow chart showing a manufacturing method of the light emitting diode according to the present invention.

As shown in FIG. 8, the manufacturing method of the light emitting diode according to the invention can be divided into eight processes.

The manufacturing method includes a cleaning process (S1) in which contaminants on a wafer are removed, an activation process (S2) in which cathodic treatment for discharging or increasing electrons is performed and P—GaN, the n-type nitride semiconductor layer, and the active layer are grown, a mesa forming process (S3), a p-type electrode forming processes (S4 to S6) in which a p-type electrode is formed on the upper portion of the p-type nitride semiconductor layer, that is, in which p-type ohmic metal is formed (S4), barrier metal is formed on the p-type ohmic metal (S5), and the bonding metal is formed on the barrier metal (S6), an etching process (S7) in which, after an insulating body is formed on the light emitting structure and p-type electrode including the mesa, the insulating body is etched so that a portion of the bonding metal of the p-type electrode and the n-type nitride semiconductor layer of the mesa are exposed, and an n-type ohmic metal forming process (S8) in which the n-type electrode is formed across the insulating layer and the mesa so as to come in contact with the exposed n-type nitride semiconductor layer, that is, in which the n-type ohmic metal is formed. Through the manufacturing method, a light emitting diode chip is manufactured.

Specifically, the mesa is formed through a cleaning process, a photo process, an etching process, a stripping process, and a thickness measuring process. The p-type ohmic metal, the n-type ohmic metal, the barrier metal, and the bonding metal are formed through a cleaning process, a photo process, preprocessing, a lift-off process, and an annealing process. The insulating layer is formed through a cleaning process, a photo process, an etching process, a stripping process, and a cleaning process.

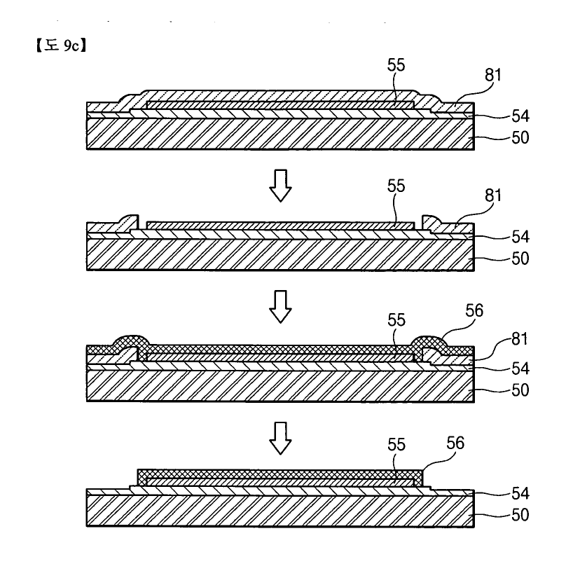

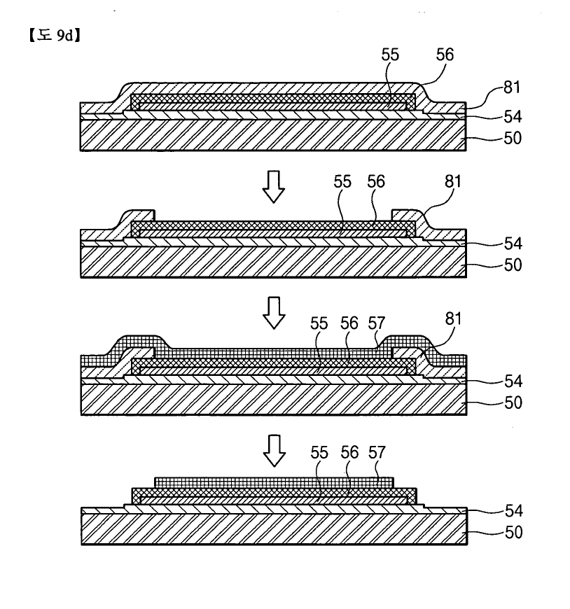

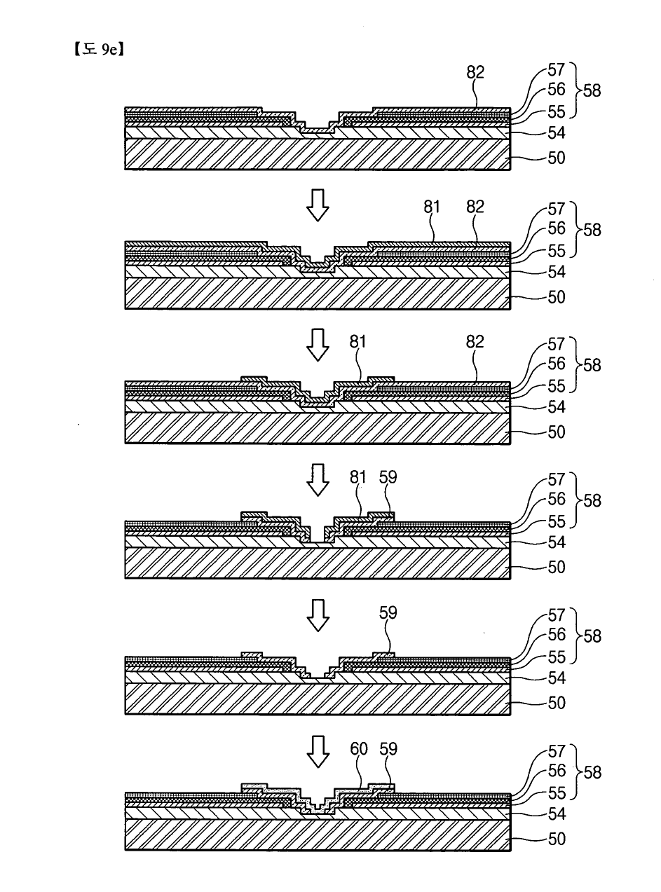

FIGS. 9A to 9E are cross-sectional views showing a manufacturing process of the light emitting diode according to the invention. The above-described processes will be described in detail with reference to the drawings.

FIG. 9A shows a process of forming the mesa. Positive photoresist 80 is coated on the light emitting structure 54 is then etched by using an RIE method, thereby forming the mesa. At this time, etching can be performed while the width of the mesa is adjusted.

FIG. 9B shows a process of forming the p-type ohmic metal 55. On the light emitting structure 54, the negative photoresist 81 is coated. After the negative photoresist 80 is developed, the p-type ohmic metal 55 is laminated. The p-type ohmic metal 55 is formed through a lift-off method. The developing process is to remove a predetermined portion of photoresist by using a developing solution, in order to form an image while necessary and unnecessary portions thereof are discriminated. The lift-off method is where photoresist is coated, a crystal portion irradiated with spot-shaped ultraviolet rays is developed, the photoresist is removed, and a light shielding film such as chrome is then deposited so that the photoresist and a non-crystal portion of chrome are removed.

FIG. 9C shows a process of forming the barrier metal 56. On the light emitting structure 54 and the p-type ohmic metal 55, the negative photoresist 81 is coated. After the negative photoresist 81 is developed, the barrier metal 56 is laminated. The barrier metal 56 is formed through a lift-off method.

FIG. 9D shows a process of forming the bonding metal 57. As in the processes of forming the p-type ohmic metal and barrier metal of FIGS. 9B and 9C, the negative photoresist 81 is coated on the light emitting structure 54 and the barrier metal 56. After the negative photoresist 81 is developed, the bonding metal 57 is laminated. The bonding metal 57 is formed through a lift-off method.

FIG. 9E shows a process of forming the insulating layer 59 and the n-type electrode 60. On the light emitting structure 54 including the mesa and the plurality of p-type electrodes 58, an insulating body 82 formed of a transparent nonconductor film is laminated, and the negative photoresist 81 is coated. After the negative photoresist 81 is developed, a portion of the insulating body 82 is etched so that a portion of the bonding metal 57 of the formed p-type electrode 58 which is bonded to the anode of a submount and a portion of the n-type nitride semiconductor layer 51 of the mesa are exposed. After that, the remaining photoresist 81 is removed, thereby forming the insulating layer 59.

The insulating layer 59 can be formed across the surface of the light emitting structure from a portion of the barrier metal 56 of the p-type electrode 58, excluding a portion where the barrier metal 56 comes in contact with the bonding metal 57, to a portion of the n-type nitride semiconductor layer of the mesa (not shown). However, the insulating layer 59 cannot be formed from a portion where the barrier metal 56 comes in contact with the bonding metal 57. That is because, if the insulating layer 59 is formed from a portion where the barrier metal 56 comes in contact with the bonding metal 57, the n-type electrode 60 formed on the insulating layer 59 comes in contact with the bonding metal 57 so that a short-circuit can occur.

The n-type ohmic metal is formed the same as the p-type ohmic metal. The n-type electrode 60 is formed by laminating the n-type ohmic metal across the insulating layer 59 and the mesa so that the n-type ohmic metal comes in contact with the exposed n-type nitride semiconductor layer of the mesa.

While the present invention has been described with reference to exemplary embodiments thereof, it will be understood by those skilled in the art that various changes and modifications in form and detail may be made therein without departing from the scope of the present invention as defined by the following claims.

According to the flip chip light emitting diode and the method of manufacturing the same of the present invention, the n-type electrode is formed on the insulating layer, so that the width of the mesa can be minimized compared with an existing chip. Accordingly, a light emitting area is expanded, and a current-spreading effect can be enhanced.

Furthermore, since the n-type electrode formed on the insulating layer serves as a reflecting layer, the light transmitted into the rear surface is blocked and is simultaneously reflected to the inside, thereby enhancing the light emission efficiency.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

### DRAWINGS

[FIG. 8]
S1: CLEANING
S2: ACTIVATION
S3: MESA
CLEANING, PHOTO PROCESS, ETCHING, STRIPPING, THICKNESS MEASURING
S4: P-TYPE OHMIC METAL
CLEANING, PHOTO PROCESS, PREPROCESSING, LIFT-OFF, ANNEALING
S5: BARRIER METAL
CLEANING, PHOTO PROCESS, PREPROCESSING, LIFT-OFF, ANNEALING
S6: BONDING METAL
CLEANING, PHOTO PROCESS, PREPROCESSING, LIFT-OFF, ANNEALING
S7: LAMINATING INSULATING LAYER
CLEANING, PHOTO PROCESS, ETCHING, PR STRIPPING, CLEANING
S8: N-TYPE OHMIC METAL
CLEANING, PHOTO PROCESS, PREPROCESSING, PR STRIPPING, CLEANING

What is claimed is:

1. A flip chip light emitting diode comprising:
an optically-transparent substrate;
a light emitting substrate that is formed by sequentially laminating an n-type nitride semiconductor layer, an active layer, a p-type nitride semiconductor layer on the substrate and that includes mesas which are formed by etching the active layer and the p-type nitride semiconductor layer into a predetermined width so that a plurality of regions of the n-type nitride semiconductor layer are exposed;
a plurality of p-type electrodes that are formed on the p-type nitride semiconductor layer of the light emitting structure;
an insulating layer that is formed on the surface of the light emitting structure from a portion of the plurality of p-type electrodes to a portion of the n-type nitride semiconductor layer of the mesa; and
an n-type electrode that is formed across the insulating layer and the mesa and comes in contact with the exposed n-type nitride semiconductor layer of the mesa.

2. The flip chip light emitting diode according to claim 1,
wherein the width of the mesa of the light emitting structure is in the range of 5 to 25 μm.

3. The flip chip light emitting diode according to claim 1,
wherein the plurality of p-type electrodes are formed by sequentially laminating p-type ohmic metal, barrier metal, and bonding metal.

4. The flip chip light emitting diode according to claim 3,
wherein the insulating layer is formed across the surface of the light emitting structure from a portion of the barrier metal or bonding metal to a portion of the n-type nitride semiconductor layer of the mesa.

5. A method of manufacturing a flip chip light emitting diode comprising:
sequentially forming an n-type nitride semiconductor layer, an active layer, a p-type nitride semiconductor layer on an optically-transparent substrate;
etching predetermined regions of the active layer and p-type nitride semiconductor layer and exposing a plurality of regions of the n-type nitride semiconductor layer so as to form a plurality of mesas;
forming a plurality of p-type electrodes on the p-type nitride semiconductor layer;
forming an insulating body on a light emitting structure including the mesas and the plurality of p-type electrodes and then etching the insulating body so that portions of the plurality of p-type electrodes and the n-type nitride semiconductor layer of the mesa are exposed; and
forming an n-type electrode across the insulating layer and the mesa so that the n-type electrode comes in contact with the exposed n-type nitride semiconductor layer of the mesa.

6. The method of manufacturing a flip chip light emitting diode according to claim 5,
wherein, in forming the mesa, etching is performed so that the width of the mesa corresponds to the range of 5 to 25 μm.

7. The method of manufacturing a flip chip light emitting diode according to claim 5,
wherein, in forming the p-type electrode, p-type ohmic metal, barrier metal, and bonding metal are sequentially laminated.

8. The method of manufacturing a flip chip light emitting diode according to claim 7,
wherein, in forming the insulating layer, the insulating body is etched so that a portion of the barrier metal, the overall portion of the bonding metal, and a portion of the bonding metal are exposed.
